(19) United States
(12) Patent Application Publication
(10) Pub. No.: US 2011/0048496 A1
(43) Pub. Date: Mar. 3, 2011

(54) SOLAR REFLECTOR

(75) Inventors: Edwin Foong, New South Wales (AU); Rohan Gillespie, New South Wales (AU)

(73) Assignee: SOLEIR LTD, New South Wales (AU)

(21) Appl. No.: 12/812,739

(22) PCT Filed: Oct. 17, 2008
(86) PCT No.: PCT/AU08/01530

§ 371 Date: Nov. 15, 2010

(30) Foreign Application Priority Data
Jan. 6, 2008 (AU) 2008100048
Oct. 17, 2008 (AU) PCT/AU2008/001530

(51) Int. Cl. F24J 2/12; F24J 2/52; F24J 2/02; H01L 31/052; H01L 31/18

(52) U.S. Cl. 136/246; 29/890.033; 126/694; 126/634

(57) ABSTRACT

In one embodiment of the invention, there is provided a solar reflector assembly comprising a corrugated support structure and a reflector panel. The support structure includes a plurality of support panels each having a generally U or V-shaped cross-section. The support panels are interlocked and connected to a lower facing surface of the reflector panel which is designed to reflect and concentrate light energy. The solar reflector assembly of this embodiment may further comprises a solar absorber in the form of a pipe and/or including photovoltaic strip for collecting the concentrated the light energy.

### FIELD OF THE INVENTION

The present invention relates broadly to a method of constructing a solar reflector assembly together with the solar reflector assembly itself.

### BACKGROUND OF THE INVENTION

There exists in Australia and elsewhere several solar thermal array systems which are designed to convert solar energy into electricity via the heating of water or other liquids to drive electricity generating turbines. Such systems typically involve an elaborate structure which supports parabolic solar reflectors where the structure can pivot with the position of the sun so as to constantly concentrate reflected sunlight onto overhead pipes through which the liquid is heated and delivered to a heat engine or heat exchanger. As the fuel (in the form of sunlight) for such systems is renewable and essentially free, a challenge for making such systems economically viable, involves the design and construction of low cost pivoting structures to support the solar reflectors.

### SUMMARY OF THE INVENTION

According to one aspect of the present invention there is provided a method of constructing a solar reflector assembly, said method comprising the steps of:
forming a plurality of support panels each having at least one adjacent ridge and groove;
interconnecting adjacent of the support panels to form a corrugated support structure; and
mounting a reflector panel to the support structure whereby its reflective surface is configured to reflect and concentrate light energy.

Preferably the step of forming the support panels involves roll forming sheet metal. More preferably the roll forming is cold roll forming.

Preferably the method further comprises, prior to the step of mounting the reflector panel, the step of roll forming the reflector panel to include the reflective surface. More preferably the step of roll forming the reflector panel includes cold roll forming sheet metal to include a parabolic shaped reflective surface having a linear focal region.

Preferably the method also comprises the step of mounting a solar absorber to the reflector panel and/or the corrugated support structure for collecting the concentrated light energy. More preferably the step of mounting the solar absorber includes the step of locating the solar absorber at or near the linear focal region.

According to another aspect of the invention there is provided a solar reflector assembly comprising:
a corrugated support structure including a support panel having at least one adjacent ridge and groove; and
a reflector panel supported by the corrugated support structure and designed to reflect and concentrate light energy.

Preferably the support panel is one of a plurality of elongate support panels each having a generally U or V-shaped trapezoidal-shaped cross-section formed by a pair of inclined side flanges interconnected by an intermediate web. More preferably the plurality of support panels are held together by interlocking the side flanges of adjacent support panels.

Preferably the reflector panel includes a curved reflective surface of a parabolic shape having a linear focal region.

Preferably the support structure also includes a plurality of transverse ribs each having a curved edge connected to an upper facing surface of the reflector panel and shaped to promote the parabolic shape of the curved reflective surface. More preferably the transverse ribs are equally spaced longitudinally along the reflector panel and extend transverse to the support panels with the reflector panel sandwiched between the support panels and the transverse ribs.

Preferably the solar reflector assembly further comprises a solar absorber for collecting the concentrated light energy. More preferably the solar absorber is located at or near the linear focal region.

Preferably the solar absorber includes a solar absorber pipe adapted for a fluid to flow. More preferably the fluid is a liquid adapted to absorb the heat reflected and concentrated by the reflector panel. Even more preferably the heat absorbed by the liquid is used to generate electricity:

Preferably the solar absorber includes a photovoltaic material adapted to absorb the light energy reflected and concentrated by the reflector panel. More preferably the light energy absorbed by the photovoltaic material is used to generate electricity. Even more preferably the photovoltaic material forms at least part of a photovoltaic strip.

Preferably the solar reflector assembly also comprises support plates connected to respective ends and/or intermediate sections of the elongate support panels. More preferably at least one of the support plates is pivotally mounted to a support pedestal and operatively coupled to drive means for rotating the reflector panel for tracking of the sun's movement. Alternatively at least one of the support plates is connected to an actuator hoop which is operatively coupled to drive means for rotating the reflector panel.

### BRIEF DESCRIPTION OF THE DRAWINGS

In order to achieve a better understanding of the nature of the present invention a preferred embodiment of a method of constructing a solar reflector assembly and the solar reflector assembly itself will now be described, by way of example only, with reference to the accompanying drawings in which:

FIG. 1 is an elevational and sectional view of a solar reflector assembly according to one embodiment of the invention;

FIG. 2 is a perspective view of part of a corrugated support structure and reflective panel taken from the solar reflector assembly of FIG. 1;

FIG. 3 is an enlarged perspective view of a section of the corrugated support structure and reflector panel of FIG. 2;

FIG. 4 is a sectional view of another embodiment of a solar reflector assembly;

FIG. 5 is a sectional view of a further embodiment of a solar reflector assembly;

FIG. 6 is a sectional view of yet another embodiment of a solar reflector assembly;

FIG. 7 is a sectional view of alternative drive means taken from the embodiment of any one of FIGS. 4 to 6; and

FIG. 8 is a sectional view of a support pedestal of any one of the embodiments of the solar reflector assembly of FIGS. 4 to 6.

### DETAILED DESCRIPTION OF THE PREFERRED EMBODIMENTS

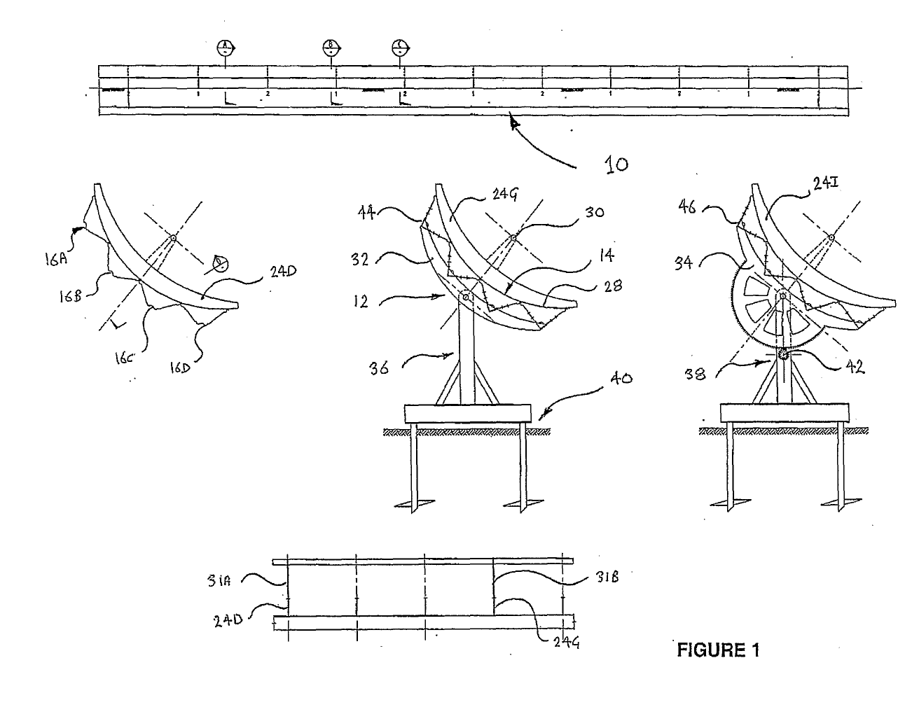

As best shown in FIG. 1 there is solar reflector assembly 10 comprising a corrugated support structure 12 and a reflector panel 14. The support structure 12 includes a plurality of support panels such as 16A to 16D each having a generally V-shaped cross-section. The support panels 16A to 16D are interlocked and connected to a lower facing surface of the reflector panel 14 which is designed to reflect and concentrate light energy.

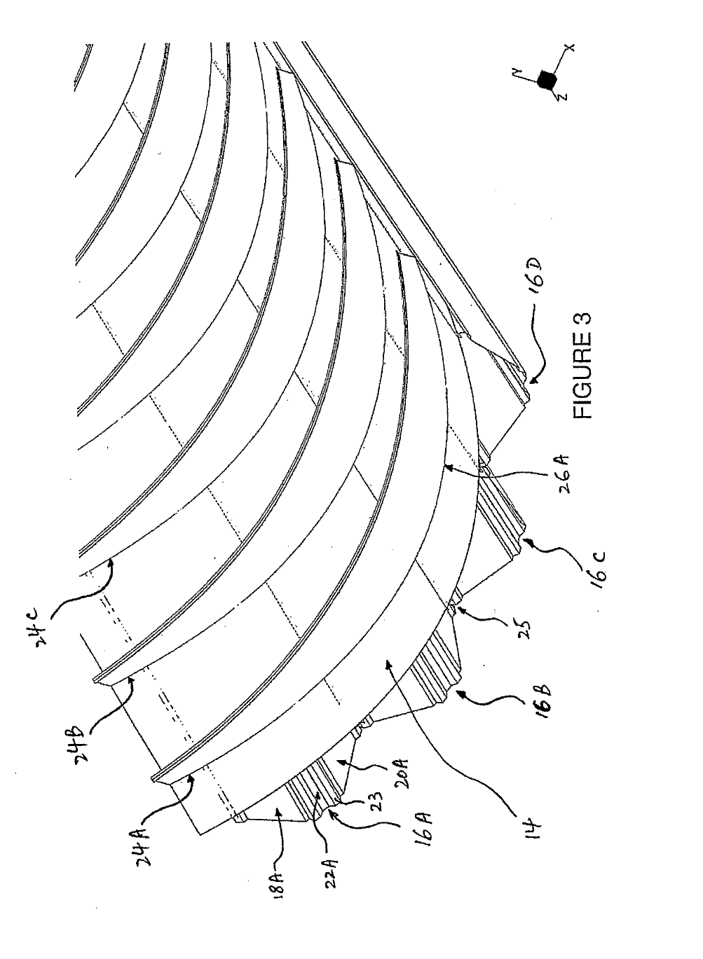

As best shown in FIG. 3, in this embodiment the V-shaped support panels such as 16A are each formed by a pair of inclined side flanges 18A and 20A interconnected by an intermediate web 22A. This cross sectional configuration defines an elongate groove or trough 23 bordered by opposing ridges such as 25. These elongate panels are otherwise constructed in accordance with Australian patent no. 726159 by Wade Hylton Blazley and its foreign counterparts. The disclosure of this Australian patent and its foreign counterparts is to be included herein by way of reference.

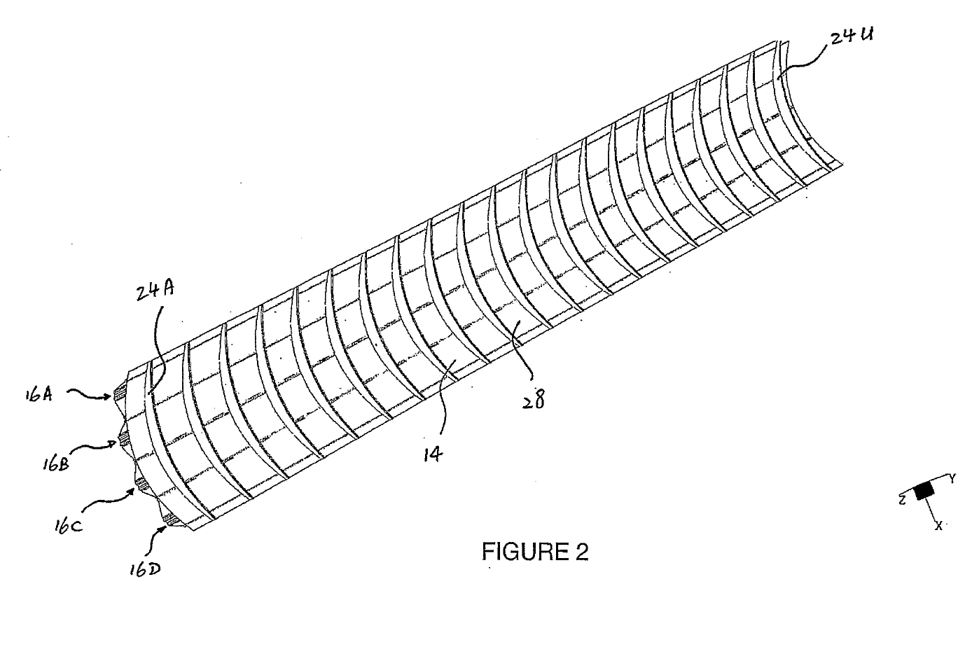

As best shown in FIG. 2, the support structure 12 of this embodiment also includes a plurality of transverse ribs such as 24A to 24U connected to an upper facing surface of the reflector panel 14. Each of the transverse ribs such as 24A has an accurately profiled curved edge such as 26A to promote the parabolic shape of the curved reflective surface 28 of the reflector panel 14. In this example the transverse ribs such as 24A are equal spaced longitudinally along the reflector panel 14 and extend transverse to the support panels 16A to 16D. In this fashion the reflective panel is sandwiched between the support panels 16A to 16D and the transverse ribs 24A to 24U.

As best shown in FIG. 1, the solar reflector assembly 10 of this example further comprises a solar absorber in the form of a pipe 30 for collecting the concentrated the light energy. The pipe 30 is located at a focal region defined by the parabolic shape of the curved reflective surface 28. The pipe 30 is a solar absorber adapted for a fluid such as oil to flow. In the case of oil, the light energy is reflected from the reflective panel 14 and concentrated on the solar absorber pipe 30 to generate heat for driving a heat engine (not shown).

In this example the solar reflector assembly 10 also comprises support plates such as 32 and 34 connected to intermediate sections of the interlocked support panels 24A to 24U. The support plates such as 32 and 34 are acuate having a similar profile to the reflector panel 14 and are pivotally mounted to respective support pedestals such as 36 and 38. The support pedestals 36 and 38 are each anchored to an underlying support foundation such as 40 which in turn is anchored to the ground. In this example every other of the support plates such as 32 pivotally idles about the corresponding pedestal 36 whereas an adjacent support plate 34 is operatively coupled to drive means in the form of a cogged wheel 42 connected to the other pedestal 38 for rotating the reflector panel 14 in a swinging motion for tracking of the sun's movement.

In this embodiment the reflector panel 14, support panels 16A to 16D and transverse ribs 24A to 24U are formed of strip metal, in particular strip steel or aluminium. The reflector panel 14, support panels such as 16A and transverse ribs such as 24A may be welded, bonded or otherwise fastened together with relative ease to form a rigid structure. The support plates such as 32 and 34 include brackets such as 44 and 46 for fixing to the support panels such as 16A. In this example the support panels such as 16A are screwed, riveted or otherwise fastened to the support plate bracket such as 44 and 46. The support panels 16 to 16D and support plates such as 32 and 34 together with the transverse ribs 24A to 24U rigidly hold the reflector panel 14 in its parabolic shape for reflection and concentration of light energy.

In some embodiments, the solar absorber may alternatively or additionally include a photovoltaic strip or strips (not shown). Photovoltaic strips typically include a photovoltaic material which generates an electric current when the photovoltaic material is exposed to sunlight or light within a certain wavelength range. In these embodiments, therefore, the photovoltaic strip or strips may absorb the sunlight reflected and concentrated by the reflective panel 14 thereby generating electricity.

In these embodiments the use of photovoltaic strips provides several advantages over the use of conventional photovoltaic panels. Firstly, since photovoltaic strips typically have a smaller footprint than photovoltaic panels, they are more suited in applications where sunlight is concentrated in space. The smaller footprint of the photovoltaic strips also helps to minimise any further burden or load on the support structure. Secondly, photovoltaic strips typically include less photovoltaic material, which is generally expensive, than do photovoltaic panels. The use of photovoltaic strips therefore presents a cost advantage over the use of conventional solar panels. Thirdly, photovoltaic strips can generally withstand higher temperatures than photovoltaic panels can, and are therefore more efficient and robust under prolonged exposure to concentrated sunlight or in a high-temperature environment.

The general steps involved in fabrication of the solar reflector assembly 10 are as follows:
1. the transverse ribs 24A to 24U are fabricated off-site having their lower acuate edge such as 26A accurately shaped in the parabolic profile;
2. the support plates such as 32 and 34 together with corresponding support pedestals such as 36 and 38 are also fabricated off-site;
3. the reflector panel 14 is fabricated from the coils of strip steel or aluminium and if required, can be roll-formed on-site using a portable roll-former; and
4. the support panels 16A to 16D are roll-formed on-site from strip steel or aluminium.

In a preferred embodiment the foundations 40 and pedestals 36 are erected first and then the support panels such as 16A attached to the pedestals 36. The reflector panel 14 is then welded or otherwise fixed to the support panels such as 16A. The transverse ribs such as 24A are then secured to the reflector panel 14.

The solar absorber pipe 30 is finally mounted to the support structure 12 via a series of support masts such as 31A and 31B connected to or formed as an extension of the corresponding transverse rib such as 24D and 24G respectively. This creates an accurate reflector parabolic shape and accurate location of the absorber pipe 30 along the linear focal region.

It wilt be understood that the specifics and order of the method of assembling and erecting the solar reflector assembly 10 may vary. For example, the reflective panel 14, support panels 16 to 16D, and transverse ribs 24A to 24U may be preassembled on the ground and lifted for fastening to the support plate such as 32 and 34 which are already pivotally mounted to the underlying pedestals such as 36 and 38 and associated foundations 40. The transverse ribs such as 24A are prefabricated by stamping, or cutting and welding.

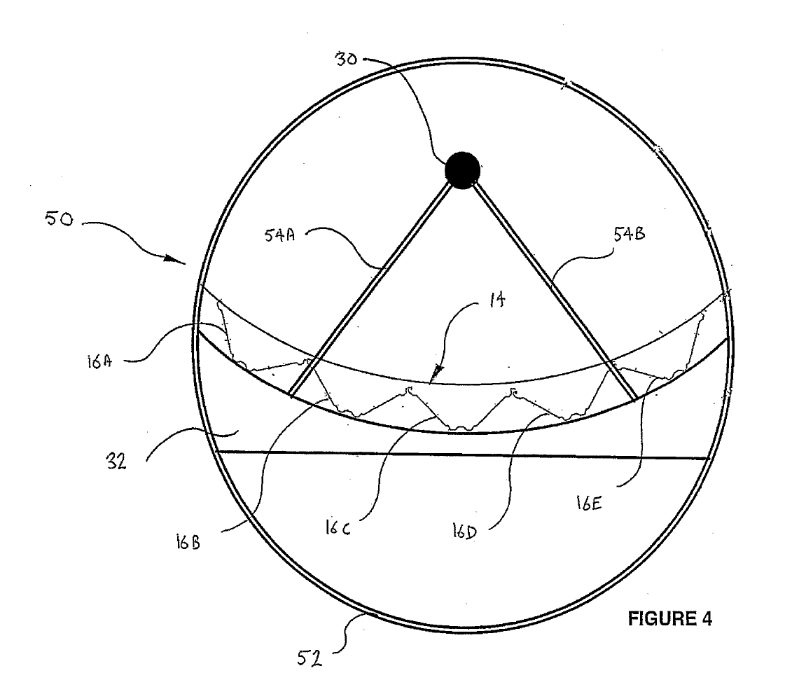

FIGS. 4 to 6 illustrate alternate embodiments of the solar reflector assembly. For ease of reference and in order to avoid repetition the same reference numerals for corresponding components and parts has been used.

The schematic sectional view FIG. 4 illustrates a solar reflector assembly 50 having what is effectively the spaced apart support plates such as 32 but having a precise parabolic profile for mounting of the support panels 16A to 16E. The reflector panel 14 is mounted on top of the support panels 16A to 16E but without the profiling assistance of the transverse rib such as 24A of the preceding embodiment. This alternate reflector assembly 50 additionally comprises a series of regularly spaced hoops such as 52 across which the support plates such as 32 and the reflector panel 14 span. The reflector assembly 50 also comprises support struts such 54A and 54B extending from the reflective panel 14 and support structure 12 meeting at the solar absorber pipe 30 for its rigid location at the focal region.

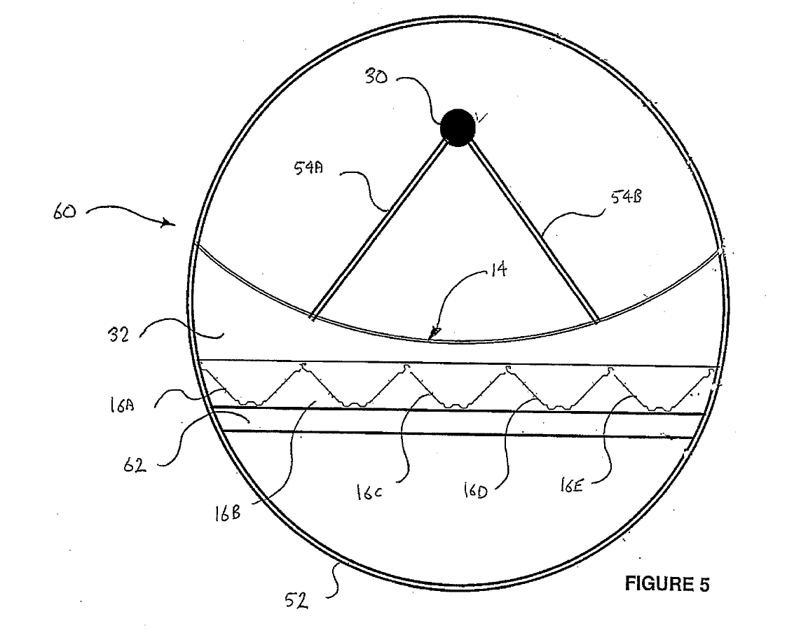

The other embodiment of FIG. 5 illustrates a reflector assembly 60 including the accurately profiled parabolic support plate 32 immediately beneath and in contact with the reflector panel 14. The support panels 16 to 16D locate underneath the support plates such as 32 and in turn are supported by an additional cross member such as 62. The cross member 62 in a similar manner to the support plate such as 32 span the hoop member such as 52.

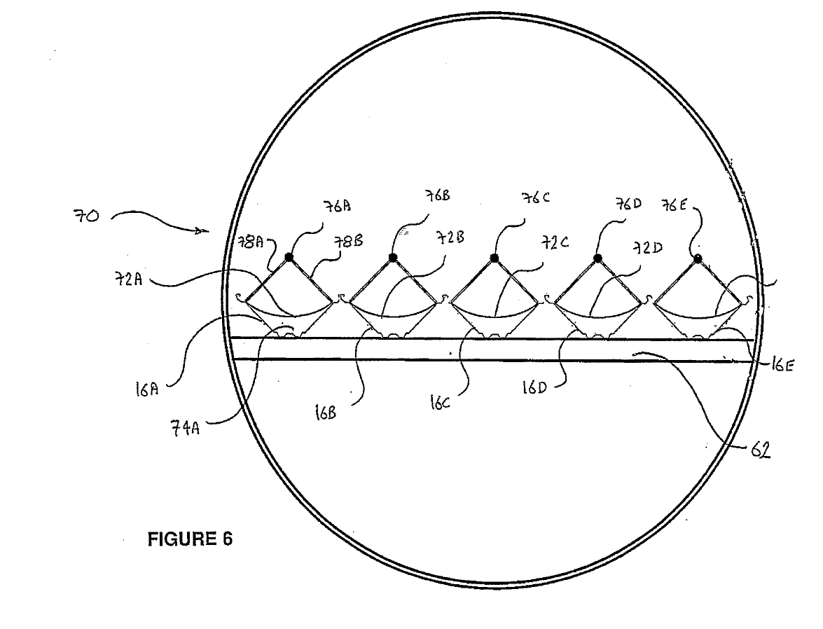

The further embodiment of FIG. 6 depicts a solar reflector assembly 70 having a plurality of reflector panels 72A to 72E each spanning a trough such as 74A of one of the dedicated support panels such as 16A. The support panels 16A to 16E are interlocked alongside one another and in a similar fashion to the embodiment of FIG. 5 are mounted upon the underlying cross member 62. The reflective panels 72A to 72E each have a dedicated solar absorber pipe 76A to 76E held at the focal region by a pair of support struts such as 78A and 78B.

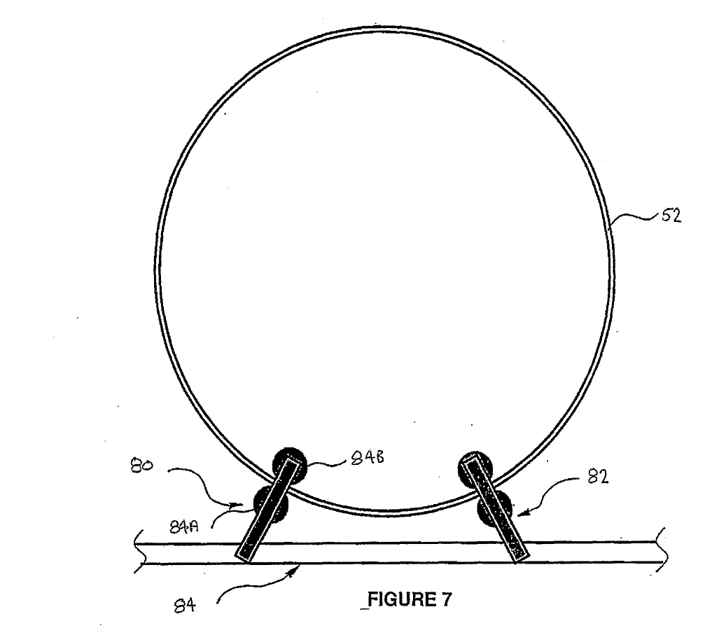

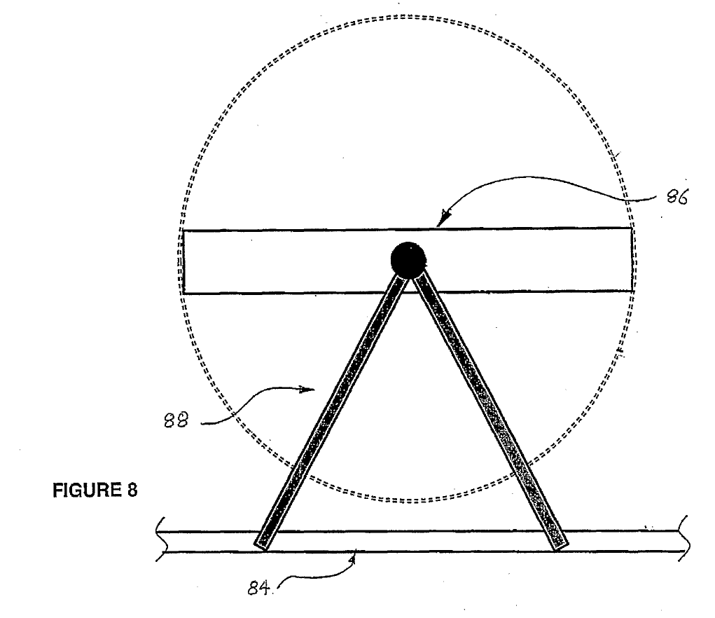

FIGS. 7 and 8 show alternate examples of drive means for rotating the alternate assemblies of FIGS. 4 to 6 in a reciprocating or swinging motion for tracking of the sun's movement. In FIG. 7 the hoops such as 52 are engaged by roller coaster style wheel supports such as 80 and 82 which are mounted to foundations 84 such as steel beams secured to the ground. The wheel supports such as 80 include a pair of wheels such as 84A and 84B located either side of the hoop 52 for its driving motion back and forth. The wheels such as 84 may friction engage the hoop 52 or be in the form of a gear wheel designed to engage corresponding teeth formed in the hoop 52. In the alternate embodiment of FIG. 8 the drive means do not require the hoops such as 52 but rather effect rotation via a central shaft and bearing arrangement 86 supported by the pedestal 88.

Now that several preferred embodiments of the invention have been described in some detail it will be apparent to those skilled in the art that the method of constructing a solar reflector assembly and the assembly itself have at the least the following advantages:
1. the preferred methodology lends itself to onsite fabrication and reduces the need for transporting finished products with their regular shapes leading to lower transportation costs;
2. overall construction times are reduced which leads to lower overall costs;
3. the solar reflector assembly by relying on the trapezoidal-shape support panels avoids the need for relatively expensive traditional space-frame structures;
4. the interlocked support panels of the reflector assembly span relatively great distances reducing vertical supports and associated structure works contributing to a reduction in overall cost.

Those skilled in the art will appreciate that the invention described herein is susceptible to variations and modifications other than those specifically described. For example, the efficiency of the solar reflector assembly may be improved by replacing the metal reflector panel with a traditional glass mirror reflector panel, or new reflector materials as they become available. The absorber pipe may, depending on heat requirements, be constructed of a proprietary solar tube having an insulating glass pipe surrounding a metal pipe for conducting fluid or more simply a metal pipe without insulation. The dimensions of the solar reflector assembly may also be altered as required to optimise performance.

All such variations and modifications are to be considered within the scope of the present invention the nature of which is to be determined from the foregoing description.

1-24. (canceled)

25. A method of constructing a solar reflector assembly, said method comprising the steps of:
roll forming from strip metal a plurality of support panels each having at least one adjacent ridge and groove;
interconnecting adjacent of the support panels to form a corrugated support structure; and
mounting a reflector panel to the support structure whereby its reflective surface is configured to reflect and concentrate light energy.

26. The method as claimed in claim 25 wherein the roll forming is cold roll forming.

27. The method as claimed in claim 25 further comprising, prior to the step of mounting the reflector panel, the step of roll forming the reflector panel to include the reflective surface.

28. The method as claimed in claim 27 wherein the step of roll forming the reflector panel includes cold roll forming sheet metal to include a parabolic shaped reflective surface having a linear focal region.

29. The method as claimed in claim 25 also comprising the step of mounting a solar absorber to the reflector panel and/or the corrugated support structure for collecting the concentrated light energy.

30. The method as claimed in claim 29 wherein the step of mounting the solar absorber includes the step of locating the solar absorber at or near the linear focal region.

31. A solar reflector assembly comprising:
a corrugated support structure including a plurality of support panels each roll formed from strip metal and having at least one adjacent ridge and groove with adjacent of the support panels being interconnected; and
a reflector panel supported by the corrugated support structure and designed to reflect and concentrate light energy.

32. The solar reflector assembly as claimed in claim 31 wherein the support panels are each elongate having a generally U or V-shaped trapezoidal-shaped cross-section formed by a pair of inclined side flanges interconnected by an intermediate web.

33. The solar reflector assembly as claimed in claim 32 wherein the plurality of support panels are held together by interlocking the side flanges of adjacent support panels.

34. The solar reflector assembly as claimed in claim 31 wherein the reflector panel includes a curved reflective surface of a parabolic shape having a linear focal region.

35. The solar reflector assembly as claimed in claim 34 wherein the support structure also includes a plurality of transverse ribs each having a curved edge connected to an upper facing surface of the reflector panel and shaped to promote the parabolic shape of the curved reflective surface.

36. The solar reflector assembly as claimed in claim 35 wherein the transverse ribs are equally spaced longitudinally along the reflector panel and extend transverse to the support panels with the reflector panel sandwiched between the support panels and the transverse ribs.

37. The solar reflector assembly as claimed in claim 31 further comprising a solar absorber for collecting the concentrated light energy.

38. The solar reflector assembly as claimed in claim 37 wherein the solar absorber is located at or near the linear focal region.

39. The solar reflector assembly as claimed in claim 37 wherein the solar absorber includes a solar absorber pipe adapted for a fluid to flow.

40. The solar reflector assembly as claimed in claim 39 wherein the fluid is a liquid adapted to absorb the heat reflected and concentrated by the reflector panel.

41. The solar reflector assembly as claimed in claim 40 the heat absorbed by the liquid is used to generate electricity.

42. The solar reflector assembly as claimed in claim 37 wherein the solar absorber includes a photovoltaic material adapted to absorb the light energy reflected and concentrated by the reflector panel.

43. The solar reflector assembly as claimed in claim 42 wherein the light energy absorbed by the photovoltaic material is used to generate electricity.

44. The solar reflector assembly as claimed in claim 42 wherein the photovoltaic material forms at least part of a photovoltaic strip.

45. The solar reflector assembly as claimed in claim 42 also comprising support plates connected to respective ends and/or intermediate sections of the elongate support panels.

46. The solar reflector assembly as claimed in claim 45 wherein at least one of the support plates is pivotally mounted to a support pedestal and operatively coupled to drive means for rotating the reflector panel for tracking of the sun's movement.

47. The solar reflector assembly as claimed in claim 45 wherein at least one of the support plates is connected to an actuator hoop which is operatively coupled to drive means for rotating the reflector panel.
